(19) United States
(12) Patent Application Publication
(10) Pub. No.: US 2008/0067549 A1
(43) Pub. Date: Mar. 20, 2008

(54) Semiconductor component

(76) Inventors: Armin Dadgar, Berlin (DE); Carsten Baer, Magdeburg (DE); Alois Krost, Berlin (DE)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 11/823,099

(22) Filed: Jun. 25, 2007

Related U.S. Application Data
(60) Provisional application No. 60/816,736, filed on Jun. 26, 2006.

(51) Int. Cl. H01L 29/205

(52) U.S. Cl. 257/201; 257/E29.091

(57) ABSTRACT

Semiconductor components such as transistor components, for example, which exist on high Al-containing active layers or layers supplying charge carriers, having a new layer construction providing increased charge carrier mobility.

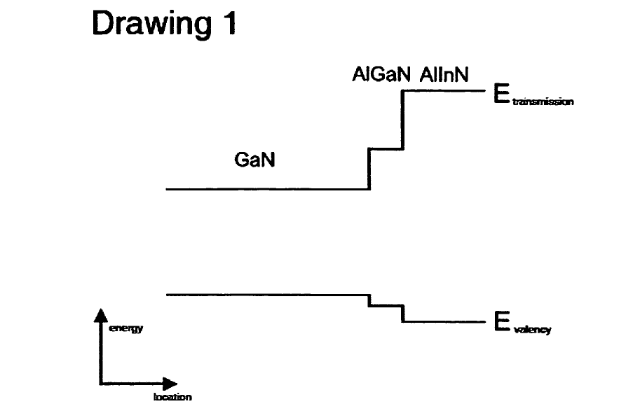

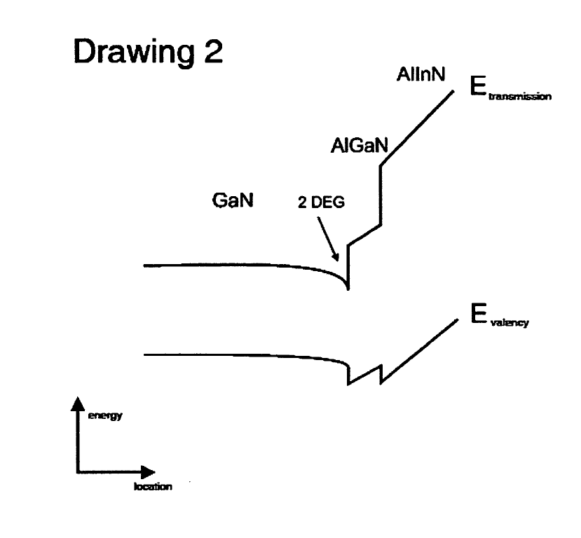

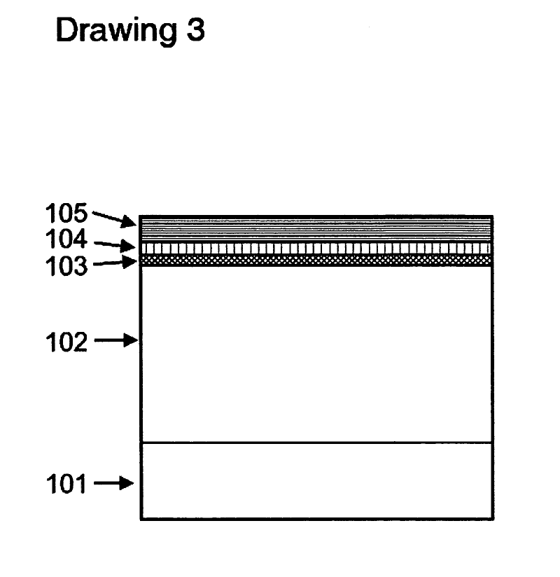

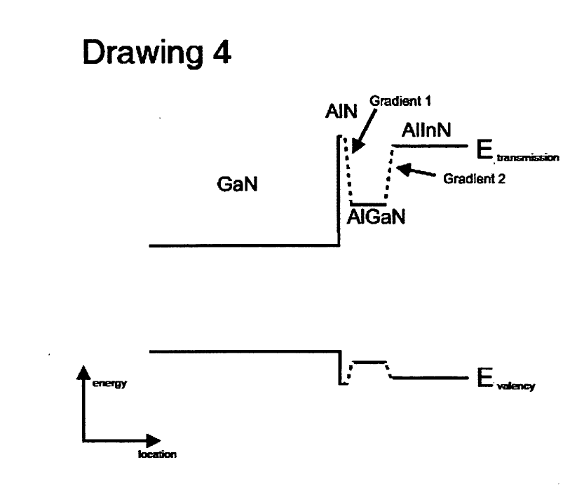

### CROSS REFERENCE TO RELATED APPLICATION

Reference is made to and priority claimed from U.S. provisional application Ser. No. 60/816,736 filed Jun. 26, 2006.

### FIELD OF THE INVENTION

The present invention pertains to the field of semiconductor components. More particularly, the present invention pertains to a semiconductor device, such as a transistor, including an aluminum compound, such as AlGaN, forming a layer of the device.

### BACKGROUND OF THE INVENTION

Transistors based on AlGaN/GaN with typical Al concentrations of around 25% and AlGaN layer thicknesses of approx. 20 nm are currently used for a multiplicity of high-frequency components. In this case a two-dimensional electron gas forms on the interface to the GaN, mainly due to piezoelectric effects, the density and charge carrier mobility of which determines the channel resistance.

A high charge carrier mobility is an essential prerequisite for high-frequency components, but it is also an important parameter for high-voltage and high-current components, which helps to determine the switching time of the component, as well as imperfections. To reduce the resistance of the channel, on the one hand the thickness of the AlGaN layer or the Al concentration thereof may be increased. An increase in the thickness here leads to a usually undesired disproportionally growing increase in the pinch-off voltage of the component and an increase in the Al concentration to a decrease in the charge carrier mobility because of alloy dispersion, in other words dispersion of the charge carriers in the two-dimensional electron gas at the interface to the GaN at potential fluctuations in the AlGaN.

A similar thing also applies to AlInN, which can be used as an alternative. AlInN is an ideal semiconductor for producing high-power transistors and diodes. AlInN with approximately 18% In (Indium) can be grown by epitaxy grid-matched to GaN, so, in contrast to the GaN/AlGaN system, the crack-free growth of thick layers becomes possible. Additionally, owing to the high spontaneous polarization fields, it is even suitable in a case where it is grid-matched to GaN, to produce transistors with high channel currents or even for making p-channel transistors for high-temperature logic circuits on a GaN basis. See e.g. DE 102004034341.1.

By comparison with conventional AlGaN-based transistors, AlInN transistors are of interest above all owing to their up to five times higher charge carrier concentration at the interface, with which in theory very low series resistances can be produced. This is possible with AlGaN only at high Al concentrations, which may lead to severe layer warping and relaxation. The main problem in making AlInN transistors is the relatively small charge carrier mobility at the interface to the GaN. This is above all due to the high dispersion of the charge carriers in the two-dimensional electron gas at the GaN/AlInN interface owing to strong potential inhomogeneities in the AlInN. This applies, even if to a slightly lesser extent, to Al-rich AlGaN layers with Al>0.35%.

In the case of GaN/AlGaN and GaN/AlInN transistor components there is to a limited extent a possibility of reducing the charge carrier dispersion by introducing AlN layers, as mentioned in DE 10 2005 021 814.8-45 and in “AlN/GaN and (Al,Ga)N/AlN/GaN two-dimensional electron gas structures grown by plasma-assisted molecular-beam epitaxy”; I. P. Smorchkova, L. Chen, T. Mates, L. Shen, S. Heikman, B. Moran, S. Keller, S. P. DenBaars, J. S. Speck und U. K. Mishra; J. Appl. Phys. 90, 5196 (2001). However, such AlN layers can be produced pseudomorphously only up to a thickness of a few monolayers, owing to the high grid mismatch to the GaN. In contrast to the application in the standard GaN/AlGaN system, in other words in the layer order GaN/AlN/AlGaN, thin AlN layers therefore have only slight effects on the charge carrier mobility in the GaN/AlInN system and the Al-rich AlGaN owing to the much stronger potential fluctuations.

It is therefore necessary to produce a functional transistor in the Al-rich AlGaInN or AlInN or AlGaN system with a two-dimensional electron gas, in which this dispersion is greatly reduced.

One could increase the thickness of the AlN layer by adding Ga or In in small amounts, which, though can ultimately do very little to prevent relaxation and, because of the high Al concentration runs counter to the actually intended goal of reduced charge carrier dispersion.

The technical problem on which the present invention is based is therefore to cite a semiconductor component in the Al-rich AlGaInN or AlInN or AlGaN system with a two-dimensional electron gas, in which the charge carrier mobility of the two-dimensional electron gas is improved compared to known solutions. Such a structure is normally found in field effect transistors (FET) or high electron mobility transistors (HEMT).

### SUMMARY OF THE INVENTION

Said technical problem is solved by the semiconductor component according to claim 1. The semiconductor component according to the invention with an AlₓGa_{y}In_{z}N layer with x>0.35, 0≦y, z≦0.65 and x+y+z=1 on an Alₓ₂Ga_{y2}In_{z2}N layer with y2>0.5 and x2+y2+z2=1 additionally has an Alₓ₃Ga₁₋ₓ₃N interfacial layer of 1-15 nm thickness and x3≦0.3 between the AlₓGa_{y}In_{z}N layer and the Alₓ₂Ga_{y2}In_{z2}N layer.

### BRIEF DESCRIPTION OF THE DRAWINGS

Drawing 1 is a schematic band course of a structure as an example of AlInN on a GaN buffer layer (y2=1) without approximate consideration of the piezoelectric fields.

Drawing 2 is a schematic band course of a structure as an example of AlInN on a GaN buffer layer (y2=1) with approximate consideration of the piezoelectric fields.

Drawing 3 is a schematic of a structure for the growth of a GaN/AlGaN/AlInN transistor structure by means of MOVPE (metal-organic vapor phase epitaxy).

Drawing 4 is a schematic of a structure having gradients of individual layers.

### DETAILED DESCRIPTION

In that in a preferred embodiment of the invention a 1-15 nanometre thick Alₓ₃Ga₁₋ₓ₃N layer, preferably with a low Al concentration of around 5-20%, has grown in front of the AlₓGa_{y}In_{z}N layer with x>0.4 and x+y+z=1, the optimum thickness of which depends on the composition of the surrounding AlGaInN layers and can be found as part of normal layer optimizations, it is possible to increase the charge carrier mobility. By contrast to said AlN layers, this layer can be grown much thicker and can thus better shield the strong potential fluctuations of the Al-rich AlₓGa_{y}In_{z}N layer.

Similarly to fears with the above-mentioned AlN layers, with a second material of smaller band gap unfavorable influencing of the course of the band or even parasitic channels are normally expected of such a structure. However, with AlN the thickness is usually so small that it is tunneled through by the charge carriers. In the interfacial layer of the semiconductor component according to the invention in some embodiments, the thickness is in fact thicker, so that such an effect cannot occur. But this is not a problem because of the smaller band gap to the Al-rich main layer, as also indicated schematically in the course of the band in drawing 2.

The typical Al concentrations of the intermediate layer or the thickness at the same concentration should be chosen lower or higher according to present findings, the higher the potential fluctuations in the following layer are. The potential fluctuations in the AlInN, are highest at approx. 25% In, in the AlGaN around 50% Al or Ga. As small a thickness as possible and an AL concentration of <30% should always be aimed at for the intermediate layer, a compromise between pinch-off voltage and mobility always having to be found in this case, as the pinch-off voltage increases with increasing intermediate layer thickness. Moreover, the thickness should be only so great that no significant intrusion in the charge carrier concentration can yet be observed and in the case of an FET the component can be pinched off at the provided voltages. A deciding factor for the latter, apart from the overall layer thickness from the surface to the channel, is the charge carrier concentration in the channel.

In addition to the solution just mentioned, in one embodiment a thin AlN layer of 0.25-5 nm thickness is introduced between the AlₓGa₁₋ₓN—, AlₓIn₁₋ₓN or AlₓGa_{y}In_{z}N layer and the Alₓ₂Ga_{y2}In_{z2}N layer.

This intermediate layer may also alternatively contain a slight amount of Ga or In, which, however, according to findings available so far, is less advantageous, though may occur during growth owing to material warping within the growth system.

A further embodiment includes the fact that indium up to a concentration of 10% is mixed into the 1-15 nanometer thick Alₓ₃Ga₁₋ₓ₃N layer to improve the potential course. A schematic band course of a structure as an example of AlInN on a GaN buffer layer (y2=1), also mentioned in the embodiment, is shown in drawing 1 without and in drawing 2 with approximate consideration of the piezoelectric fields. A high band deformation and a high electron concentration is here induced in the 2DEG (two-dimensional electron gas) channel by the AlInN with preferably a low In concentration <18% or by an Al-rich AlGaN with Al>35%, as shown schematically in drawing 2. Because of the AlGaN intermediate layer the distance of the charge carrier from the AlInN or Al-rich AlGaN or the influence of the potential fluctuations can be enabled with simultaneously sufficiently high charge carrier inclusion in the GaN. Such structures enable at least a doubling of the charge carrier mobility from the usual 150-300 cm²/Vs to over 700 cm²/Vs, as seen in table 1, and can be brought to values such as those for standard FETs, though with considerably higher charge carrier concentration.

It is clear that a particularly advantageous configuration contains both an AlN and an AlGaN layer. These intermediate layers, though slightly reducing the charge carrier concentration in the channel, do however significantly increase the charge carrier mobility. By this procedure it is possible to produce very low channel resistances with very high charge carrier mobilities.

Described below is a preferred embodiment with a structure analogous to drawing 3 for the growth of a GaN/AlGaN/AlInN transistor structure by means of MOVPE.

A GaN buffer layer 102 with trimethylgallium and ammonia is grown on a suitable substrate 101, such as, e.g. AlN, GaN, SiC, diamond, Si or sapphire. Then, normally after a short interruption in growth of usually a few seconds, growth of an AlGaN layer 104 of 5 nm thickness with trimethylaluminium, trimethylgallium and ammonia follows. If applicable, another AlN layer 103, approximately 1-1.5 nm thick, can be grown beforehand with trimethylaluminium and ammonia. Then during an interruption in growth the temperature is lowered to approx. 840° C. to grow AlInN and a 10-15 nm thick AlInN layer 105 is grown, preferably under nitrogen carrier gas, with ammonia, trimethylaluminium and trimethylindium, which contains a concentration of around 15% In.

Alternatively to abrupt transitions, it is also possible to grow gradients of the individual layers or to grow them finely graded, as seen in drawing 4. Though these transitions should be very steep at the interface to the GaN or AlN above the GaN, they are compulsorily almost always present even with theoretically abrupt transitions because of warping effects during growth.

As a first extension of this example, to increase the charge carrier mobility the AlₓGa_{y}In_{z}N high Al-containing main layers may also be doped partially or completely by a donor, such as Si or Ge, for example, in order to further increase the charge carrier concentration in the channel.

A second extension of the example is the growth of GaN, AlN or AlGaN covering layers on the AlₓGa_{y}In_{z}N layer with thicknesses of 0.25-4 nm. These covering layers are helpful in defining termination of the structure, in order to be able to check the occurring surface charges, this mainly being done by defined surface passivation layers applied thereto, which are specifically optimized to a material or a composition. During growth of such layers the entire structure has to be heated to the optimum high growth temperature for this purpose of more than 1000° C., which, when main layers of AlInN, for example, are used, may lead to segregation of the In, which can be checked by the methods mentioned in DE 10 2004 055 636.9.

Because of the high Al content of the top layers forming the basis of the invention, this structure is above all suitable for high-voltage and high-current applications because of the good insulation properties of this layer.

For high-voltage and high-current applications the component should be produced or mounted on a substrate with good heat-conduction. This includes above all diamond, AlN and SiC, but GaN and above all Si can also be cheap alternatives to these.

The finished component does not necessarily have to be processed as a transistor structure for the applications described here. In particular for high-current and high-voltage switches, it can also be processed as a lateral or vertical Schottky diode, the high-conductive channel reducing the resistance in transmission operation.

The invention includes all semiconductor production methods and layers with low amounts of an another group III element, such as boron, or alloys such as AlInGaN also in conjunction with GaN layers which contain low amounts of In, Al or B or in conjunction with AlGaN or InGaN.

TABLE I

| Layer structure | n [cm⁻²] | μ (cm²/Vs) | σ (mOhm cm) |
|---|---|---|---|
| GaN/AlInN | 5.4 × 10¹³ | 173 | 66 |
| GaN/AlGaN/AlInN | 4.5 × 10¹³ | 305 | 45 |
| GaN/AlN/AlGaN/AlInN | 4.5 × 10¹³ | 719 | 19 |
| GaN/AlN/AlGaN, | 2 × 10¹³ | 837 | 30 |
| standard FET | | | |

What is claimed is a:

1. Semiconductor component with a AlₓGa_{y}In_{z}N layer with x>0.35, 0≦y, z≦0.65 and x+y+z=1 on a Alₓ₂Ga_{y2}In_{z2}N layer with y2>0.5 and x2+y2+z2=1, characterized by an Alₓ₃Ga₁₋ₓ₃N interfacial layer of 1-15 nm thickness and x3≦0.3 between the AlₓGa_{y}In_{z}N layer and the Alₓ₂Ga_{y2}In_{z2}N layer.

2. Semiconductor component according to claim 1, characterized by an intermediate layer of AlN of 0.25-5 nm thickness between the Alₓ₂Ga_{y2}In_{z2}N layer and the Alₓ₃Ga₁₋ₓ₃N layer.

3. Semiconductor component according to claim 1, characterized by an intermediate layer of AlGaInN of 0.25-7 nm thickness and an admixture of less than 10% In and/or less than 20% Ga between the Alₓ₂Ga_{y2}In_{z2}N layer and the Alₓ₃Ga₁₋ₓ₃N layer.

4. Semiconductor component according to claim 1, characterized in that indium is added in concentrations of ≦10% to the Alₓ₃Ga₁₋ₓ₃N layer.

5. Semiconductor component according to claim 1, characterized in that the Alₓ₃Ga₁₋ₓ₃N interfacial layer is formed by a plurality of Alₓ₃Ga₁₋ₓ₃N interfacial sub-layers with x3≦0.3, the overall thickness of the interfacial sub-layers not exceeding 15 nm.

6. Semiconductor component according to claim 2, characterized in that a graduated AlGaInN layer of a maximum 4 nm thickness is arranged between the intermediate layer of AlN and the Alₓ₃Ga₁₋ₓ₃N layer.
